(19) United States
(12) Patent Application Publication
(10) Pub. No.: US 2024/0055315 A1
(43) Pub. Date: Feb. 15, 2024

(54) SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Chih-Wei Wu, Yilan County (TW); Ying-Ching Shih, Hsinchu City (TW); An-Jhih Su, Taoyuan City (TW); Wen-Chih Chiou, Miaoli County (TW)

(73) Assignee: Taiwan Semiconductor Manufacturing Company, Ltd., Hsinchu (TW)

(21) Appl. No.: 17/886,466

(22) Filed: Aug. 12, 2022

(51) Int. Cl. H01L 23/367; H01L 23/31; H01L 25/065; H01L 23/373; H01L 25/00; H01L 21/56; H01L 23/00

(52) U.S. Cl. CPC H01L 23/367; H01L 23/3121; H01L 25/0655; H01L 23/3738; H01L 25/50; H01L 21/561; H01L 24/97; H01L 2224/97

(57) ABSTRACT

Disclosed are a semiconductor package and a manufacturing method of a semiconductor package. In one embodiment, the semiconductor package includes an interposer substrate, a plurality of semiconductor dies, one or more heat dissipation elements and an encapsulant. The plurality of semiconductor dies are disposed on the interposer substrate. The one or more heat dissipation elements are disposed on the plurality of semiconductor dies. The encapsulant is disposed on the interposer substrate and surrounds the plurality of semiconductor dies and the one or more heat dissipation elements.

### BACKGROUND

A typical problem with miniaturization of semiconductor devices is heat dissipation during operation. A prolonged exposure of a die by operating at excessive temperatures may decrease the reliability and lifetime of the die. As such, improvements to heat transfer are still needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A through FIG. 1I schematically illustrate a process flow for manufacturing a semiconductor package in accordance with some embodiments of the present disclosure.

FIG. 2A through FIG. 2I schematically illustrate a process flow for manufacturing another semiconductor package in accordance with some alternative embodiments of the present disclosure.

FIG. 3A through FIG. 3I schematically illustrate a process flow for manufacturing yet another semiconductor package in accordance with other alternative embodiments of the present disclosure.

FIG. 4A through FIG. 4C schematically illustrate various cross-sectional views of a region R in FIG. 1D.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For structural support and/or heat dissipation purposes, a silicon bulk is bonded to rear surfaces of semiconductor dies, in which backside metal layer(s) and solder layer(s) are formed between the silicon bulk and the semiconductor dies to facilitate the bonding between the silicon bulk and the semiconductor dies. However, soldering void defects are prone to be generated when rear surfaces of the semiconductor dies are not level with each other. In addition, a singulation process becomes difficult or even impossible when the backside metal layer(s) and/or the solder layer(s) is/are thick.

The present disclosure is related to a semiconductor package and a manufacturing method thereof. In some embodiments, one or more heat dissipation elements (e.g., silicon bulks) is/are bonded to semiconductor dies to improve heat dissipation efficiency. The area of the one or more heat dissipation elements is reduced to reduce the bonding area between each heat dissipation element and corresponding semiconductor die(s), thereby reducing the defects and/or improving bond quality (e.g., reducing wafer warpage). When a singulation process is needed, the one or more heat dissipation elements are disposed in regions not traversed by the scribe lines, and regions traversed by the scribe lines are disposed with an encapsulant that is easier to cut than the one or more heat dissipation elements to facilitate the singulation process and/or to improve integrated yield. In some embodiments, backside metal layer(s) and solder layer(s) for bonding the one or more heat dissipation elements to the semiconductor dies are formed in regions not traversed by the scribe lines to facilitate the singulation process.

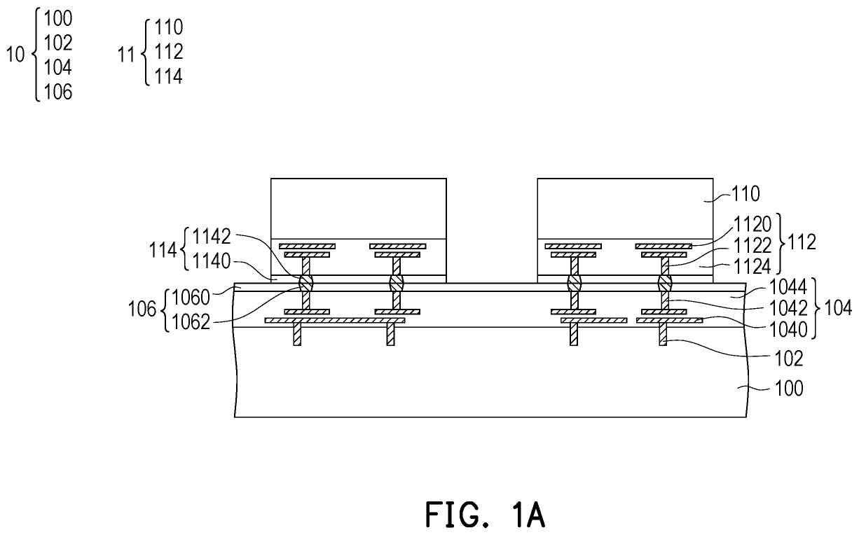

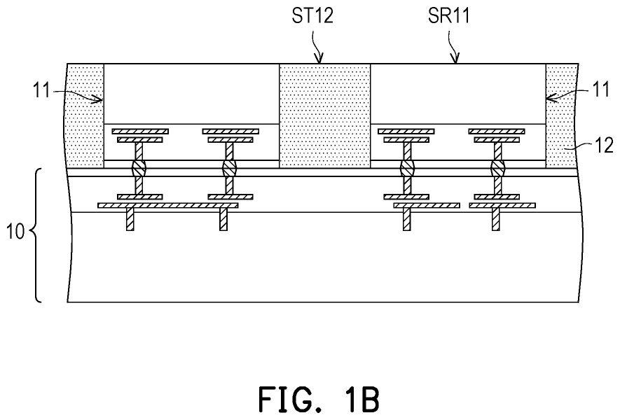

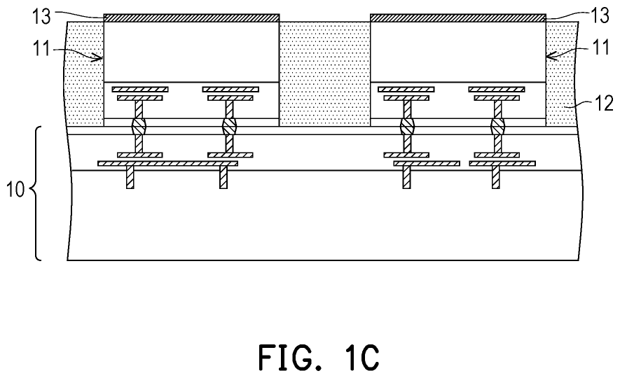

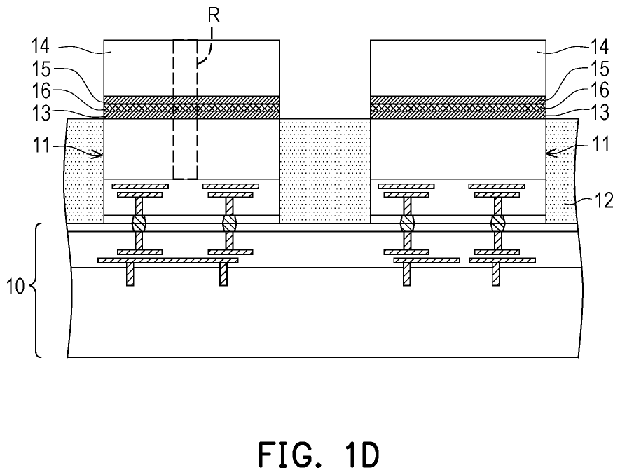

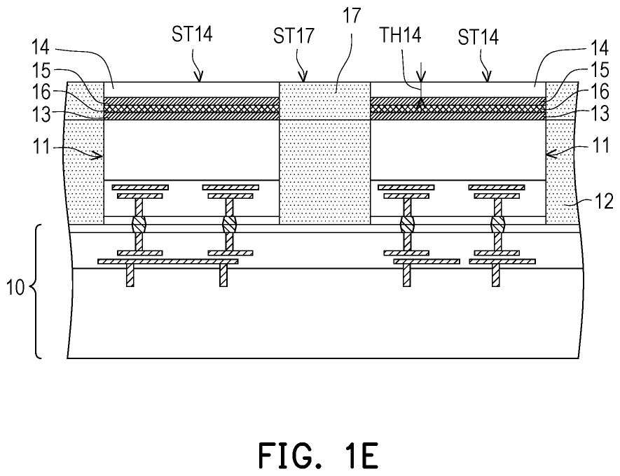

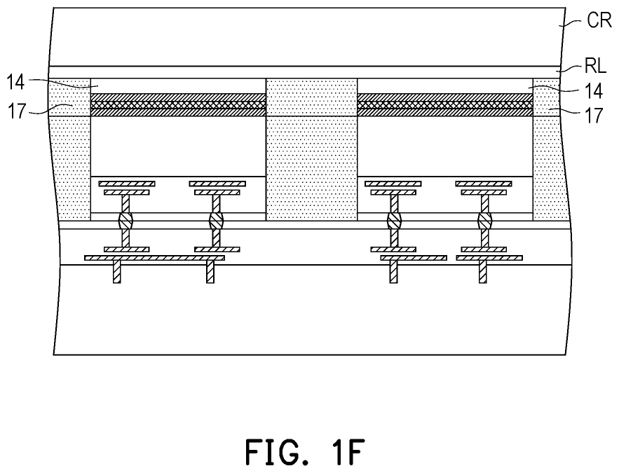

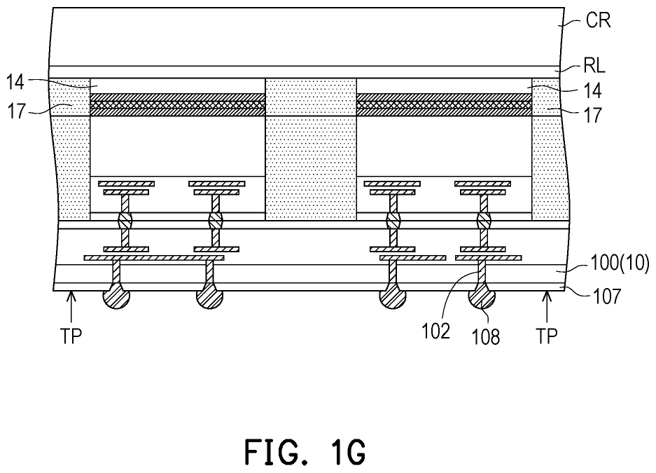

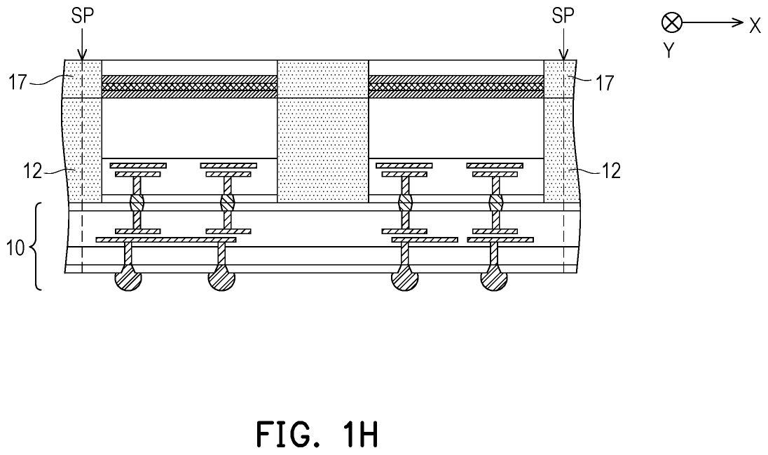

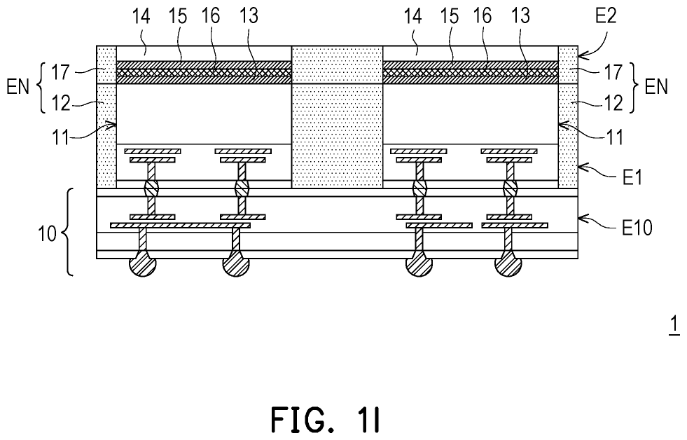

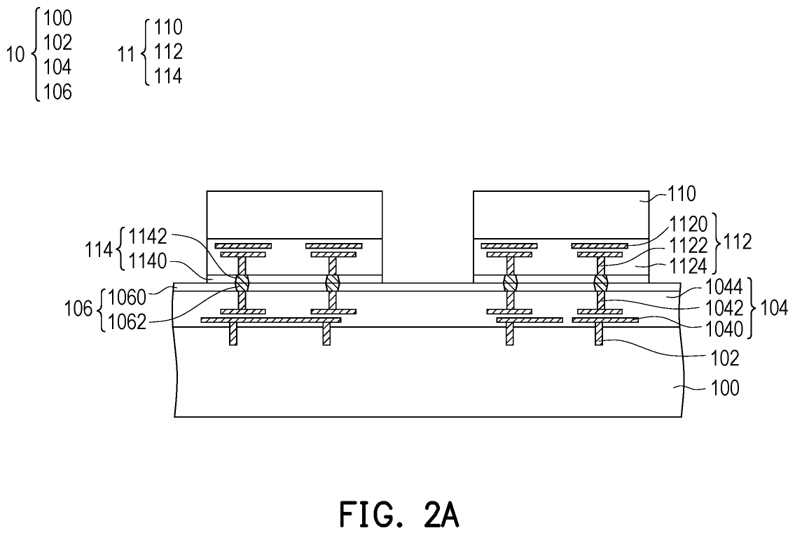

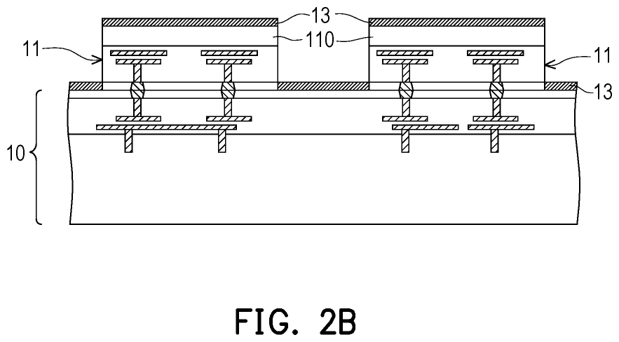

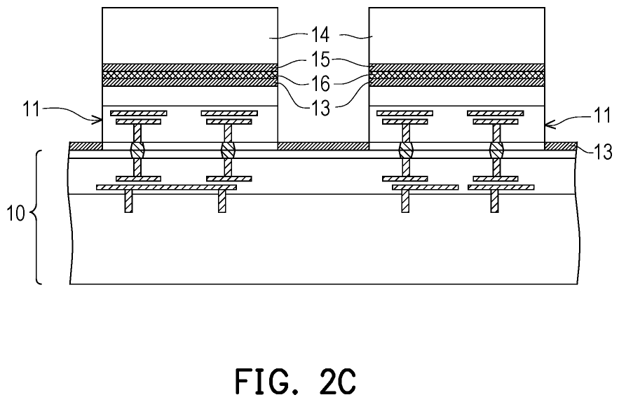

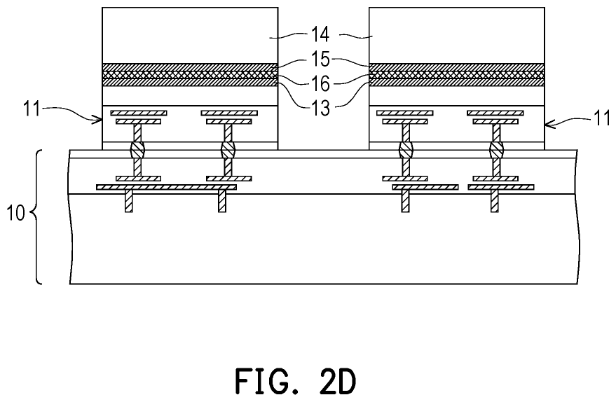

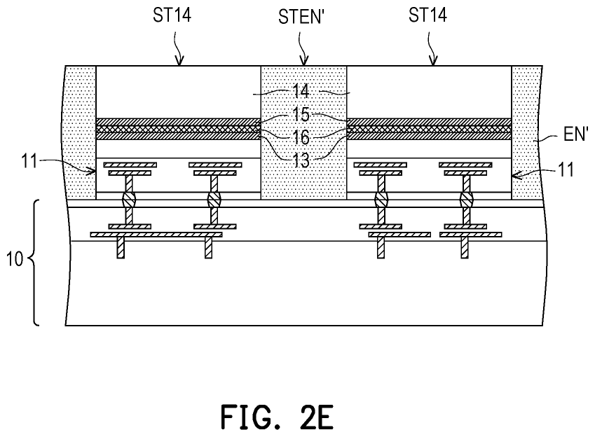

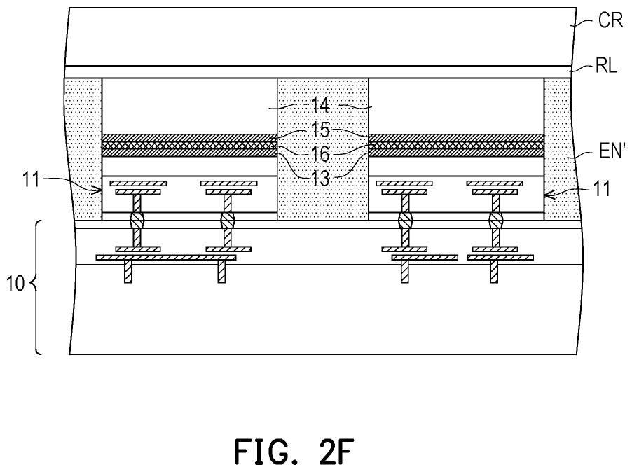

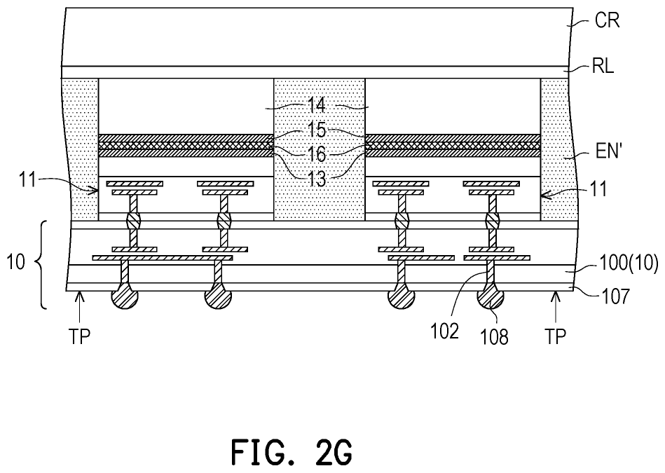

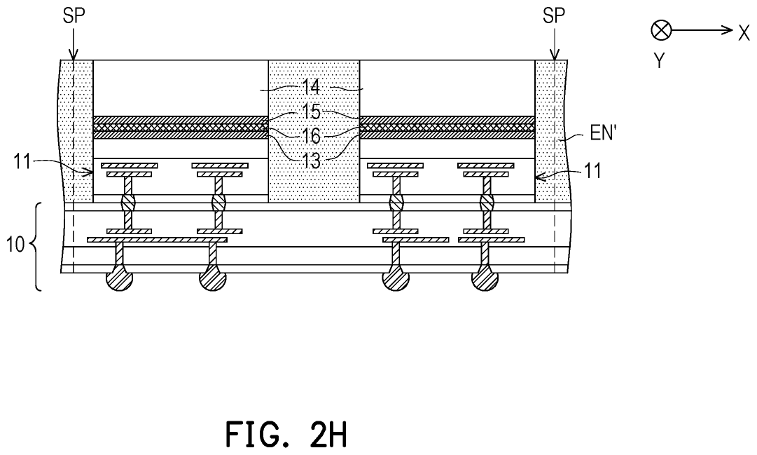

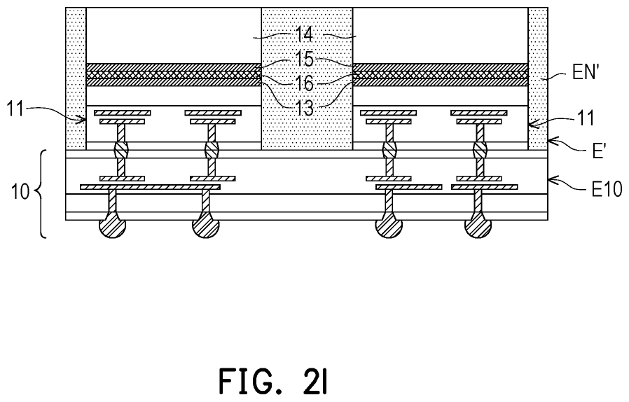

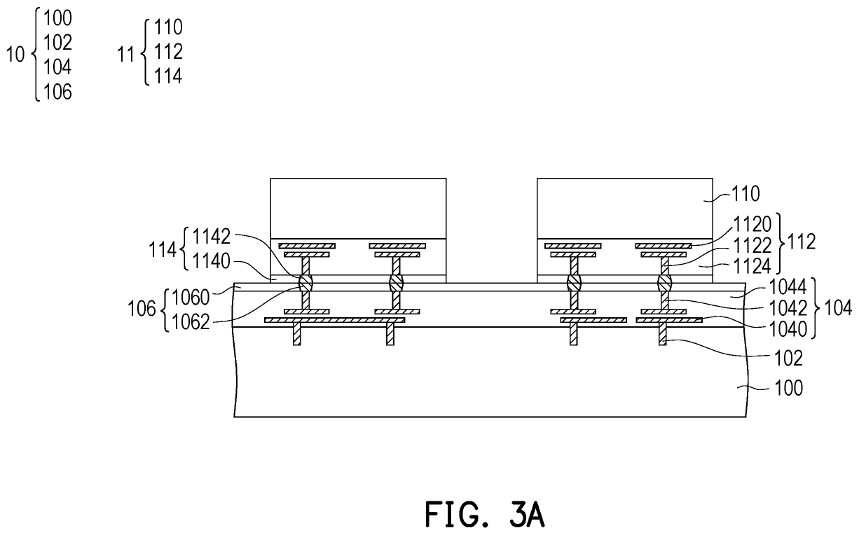

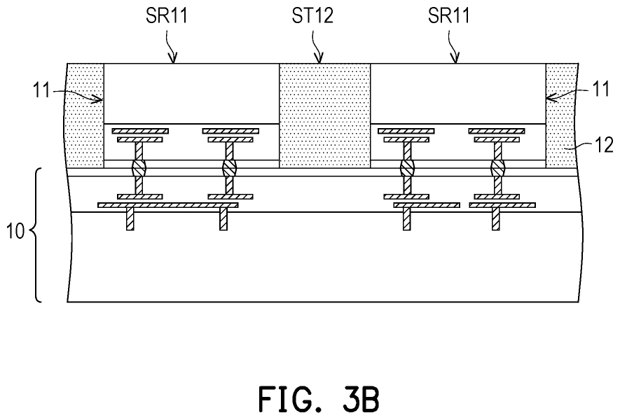

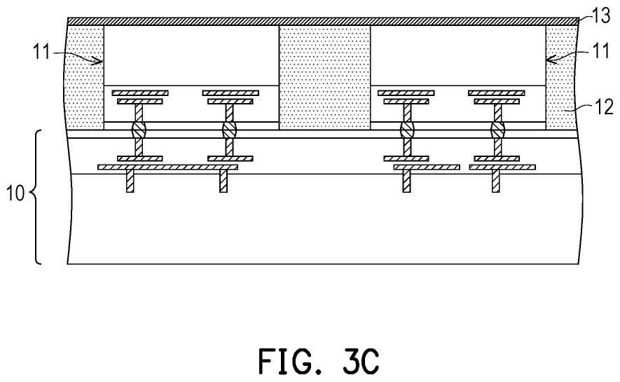

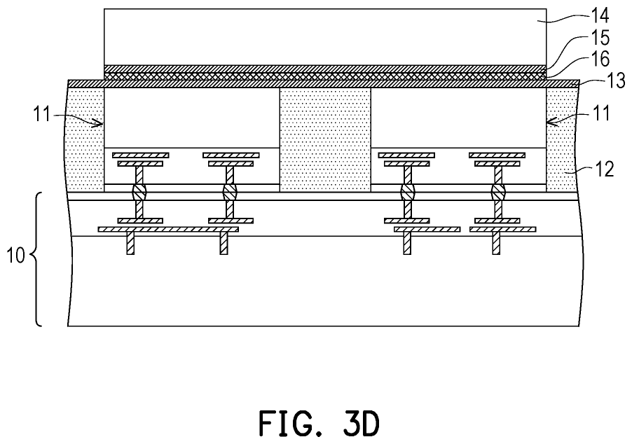

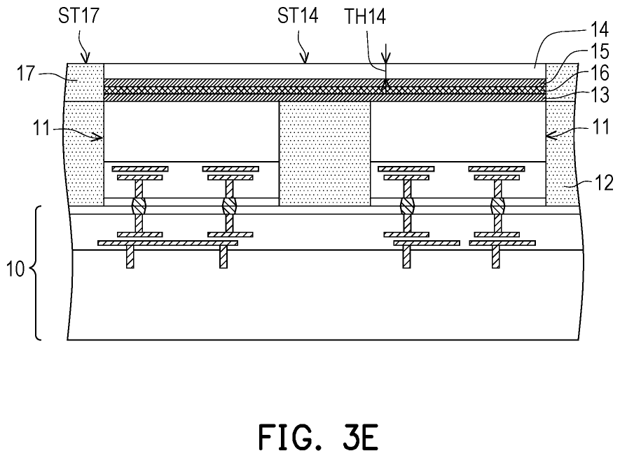

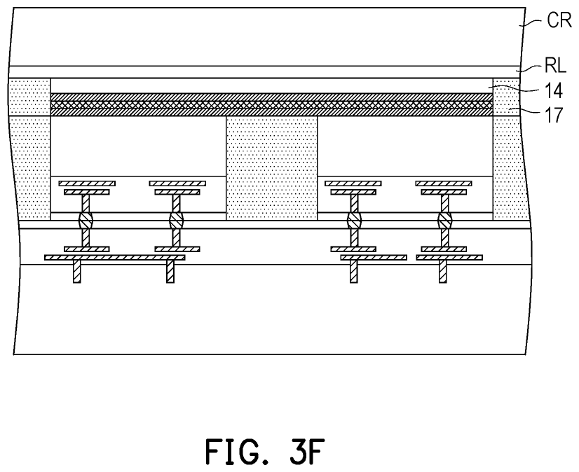

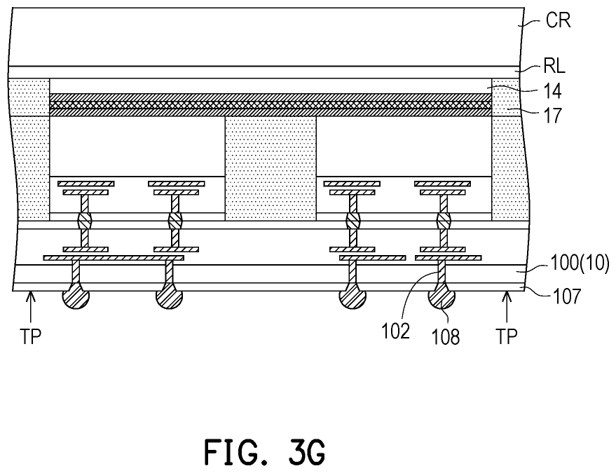

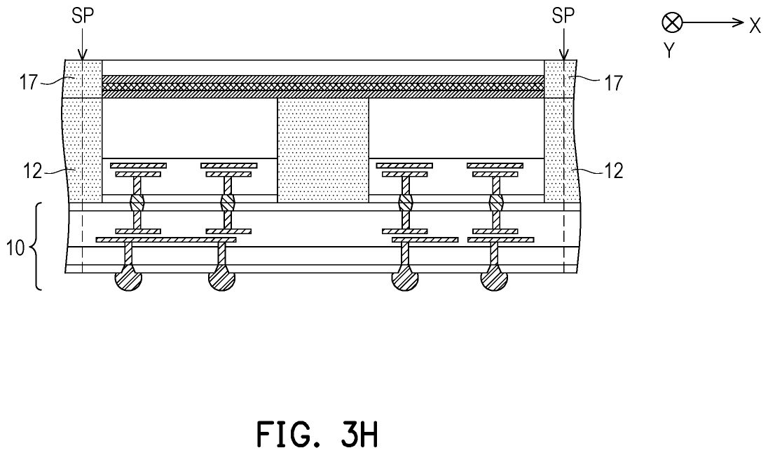

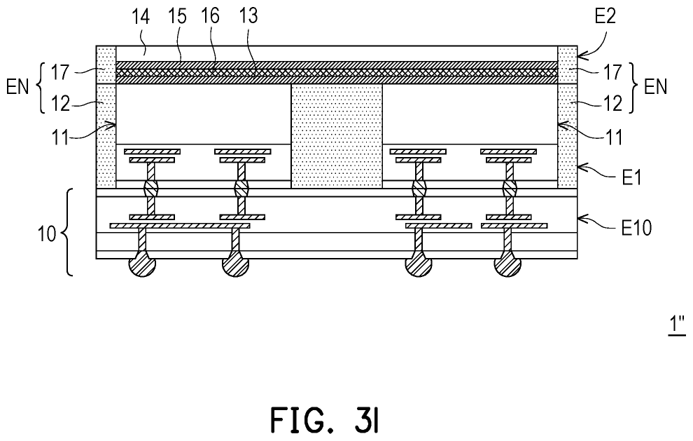

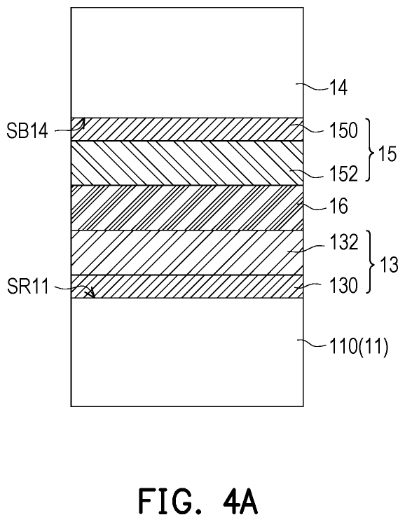

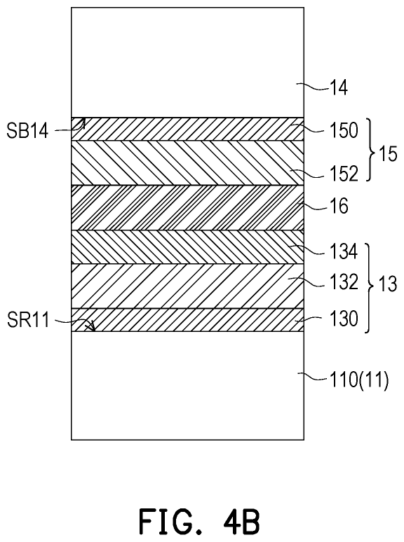

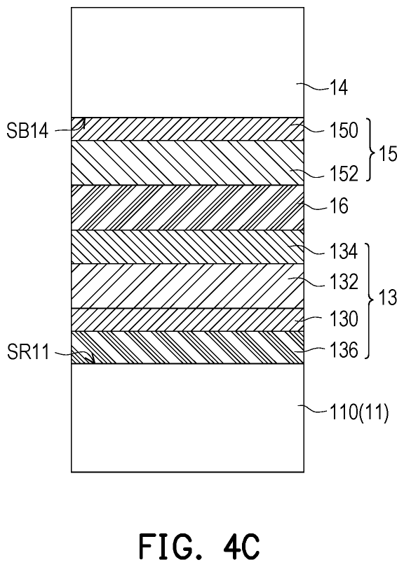

FIG. 1A through FIG. 1I schematically illustrate a process flow for manufacturing a semiconductor package in accordance with some embodiments of the present disclosure. FIG. 2A through FIG. 2I schematically illustrate a process flow for manufacturing another semiconductor package in accordance with some alternative embodiments of the present disclosure. FIG. 3A through FIG. 3I schematically illustrate a process flow for manufacturing yet another semiconductor package in accordance with other alternative embodiments of the present disclosure. FIG. 4A through FIG. 4C schematically illustrate various cross-sectional views of a region R in FIG. 1D.

Referring to FIG. 1A through FIG. 1I, a manufacturing method of a semiconductor package 1 in accordance with some embodiments of the present disclosure is provided. Referring to FIG. 1A, the manufacturing method may include bonding a plurality of semiconductor dies 11 on an interposer substrate 10.

The interposer substrate 10 may be a silicon interposer or an organic interposer, but not limited thereto. In some embodiments, the interposer substrate 10 includes a semiconductor substrate 100, through substrate vias 102, an interconnect structure 104, and a bonding structure 106, but not limited thereto.

The semiconductor substrate 100 may be or includes a monocrystalline semiconductor substrate such as a silicon substrate, a silicon-on-insulator (SOI) substrate, silicon-germanium on insulator (SGOI) or a germanium-on-insulator (GOI) substrate. In some embodiments, the semiconductor substrate 100 is made of semiconductor materials, such as semiconductor materials of the groups III-V of the periodic table. In some embodiments, the semiconductor substrate 100 includes elementary semiconductor materials such as silicon or germanium, compound semiconductor materials such as silicon carbide, gallium arsenide, indium arsenide, or indium phosphide or alloy semiconductor materials such as silicon germanium, silicon germanium carbide, gallium arsenide phosphide, or gallium indium phosphide. In some embodiments, although not shown, the semiconductor substrate 100 further include active or passive devices, such as transistors, capacitors, resistors, or diodes formed therein.

The through substrate vias 102 are formed by forming holes or recesses in the semiconductor substrate 100 and then filling the recesses with a conductive material. In some embodiments, the recesses are formed by, for example, etching, milling, laser drilling or the like. In some embodiments, the conductive material is formed by an electro-chemical plating process, chemical vapor deposition (CVD), atomic layer deposition (ALD) or physical vapor deposition (PVD), and the conductive material may include copper, tungsten, aluminum, silver, gold or a combination thereof.

The interconnect structure 104 overlies the semiconductor substrate 100 and is electrically coupled between the through substrate vias 102 and the bonding structure 106. The interconnect structure 104 may include a plurality of wires 1040, a plurality of vias 1042 and a dielectric layer 1044. Although not shown, the plurality of wires 1040 and the plurality of vias 1042 may be alternatingly stacked in the dielectric layer 1044, but not limited thereto. In some embodiments, the material of the plurality of wires 1040 and the plurality of vias 1042 includes copper or copper alloy. In some embodiments, the material of the dielectric layer 1044 includes silicon oxide, silicon nitride, undoped silicate glass material or a suitable dielectric material.

The bonding structure 106 overlies the interconnect structure 104. The bonding structure 106 may include a bonding dielectric layer 1060 and bonding conductors 1062. The bonding dielectric layer 1060 may include a plurality of contact openings, and the bonding conductors 1062 are exposed by the contact openings of the bonding dielectric layer 1060. In some embodiments, the bonding dielectric layer 1060 is formed through performing a chemical vapor deposition (CVD) process such as low-pressure CVD (LPCVD), plasma enhanced CVD (PECVD), and high-density plasma CVD (HDPCVD), and the material of the bonding dielectric layer 1060 includes silicon oxide, silicon nitride, undoped silicate glass material or a suitable dielectric material. In some embodiments, the bonding conductors 1062 is formed through performing deposition, plating, or other suitable processes, and the material of the bonding conductors 1062 includes aluminum, copper, alloy thereof or other suitable metallic material. In some embodiments, top surfaces of the bonding conductors 1062 are substantially level with a top surface of the bonding dielectric layer 1060.

The plurality of semiconductor dies 11 are individual dies singulated from the same wafer or different wafers. In some embodiments, the plurality of semiconductor dies 11 contain the same circuitry, such as devices and metallization patterns, or the plurality of semiconductor dies 11 are the same type of dies. In some alternative embodiments, the plurality of semiconductor dies 11 have different circuitry or are different types of dies.

The plurality of semiconductor dies 11 may include memory, flash, power chip, power module, converter, sensor, logic die and so on that can work in conjunction with other semiconductor elements in order to provide a desired functionality to the user. In some embodiments, the plurality of semiconductor dies 11 include digital dies, analog dies, mixed signal dies, such as application-specific integrated circuit (ASIC) dies, logic dies, sensor dies, other kinds of integrated circuit dies or a combination of the above, but is not limited thereto.

In some embodiments, each of the plurality of semiconductor dies 11 includes a semiconductor substrate 110, an interconnection structure 112 and a bonding structure 114, but not limited thereto.

The semiconductor substrate 110 may be or includes a monocrystalline semiconductor substrate such as a silicon substrate, a silicon-on-insulator (SOI) substrate, silicon-germanium on insulator (SGOI) or a germanium-on-insulator (GOI) substrate. In some embodiments, the semiconductor substrate 110 is made of semiconductor materials, such as semiconductor materials of the groups III-V of the periodic table. In some embodiments, the semiconductor substrate 110 includes elementary semiconductor materials such as silicon or germanium, compound semiconductor materials such as silicon carbide, gallium arsenide, indium arsenide, or indium phosphide or alloy semiconductor materials such as silicon germanium, silicon germanium carbide, gallium arsenide phosphide, or gallium indium phosphide. In some embodiments, although not shown, the semiconductor substrate 110 further include active or passive devices, such as transistors, capacitors, resistors, or diodes formed therein.

The interconnection structure 112 overlies the semiconductor substrate 110 and is electrically coupled to the bonding structure 114. The interconnect structure 112 may include a plurality of wires 1120, a plurality of vias 1122 and a dielectric layer 1124. Although not shown, the plurality of wires 1120 and the plurality of vias 1122 may be alternatingly stacked in the dielectric layer 1124, but not limited thereto. In some embodiments, the material of the plurality of wires 1120 and the plurality of vias 1122 includes copper or copper alloy. In some embodiments, the material of the dielectric layer 1124 includes silicon oxide, silicon nitride, undoped silicate glass material or a suitable dielectric material.

The bonding structure 114 overlies the interconnect structure 112. The bonding structure 114 may include a bonding dielectric layer 1140 and bonding conductors 1142. The bonding dielectric layer 1140 may include a plurality of contact openings, and the bonding conductors 1142 are exposed by the contact openings of the bonding dielectric layer 1140. In some embodiments, the bonding dielectric layer 1140 is formed through performing a chemical vapor deposition (CVD) process such as low-pressure CVD (LPCVD), plasma enhanced CVD (PECVD), and high-density plasma CVD (HDPCVD), and the material of the bonding dielectric layer 1140 includes silicon oxide, silicon nitride, undoped silicate glass material or a suitable dielectric material. In some embodiments, the bonding conductors 1142 is formed through performing deposition, plating, or other suitable processes, and the material of the bonding conductors 1142 includes aluminum, copper, alloy thereof or other suitable metallic material. In some embodiments, top surfaces of the bonding conductors 1142 are substantially level with a top surface of the bonding dielectric layer 1140.

In the embodiments of the disclosure, the surface where the bonding conductors 1142 are distributed on may be referred to as an active surface of the semiconductor die, and the surface opposite to the active surface of the semiconductor die may be referred to as a rear surface of the semiconductor die.

The plurality of semiconductor dies 11 may be placed onto the interposer substrate 10 through a pick-and-place method, in which active surfaces of the semiconductor dies 11 face the interposer substrate 10. Even though two semiconductor dies 11 are presented in FIG. 1A for illustrative purposes, it is understood that more than two semiconductor dies 11 can be provided on the interposer substrate 10.

In some embodiments, a bonding process is performed to bond the plurality of semiconductor dies 11 to the interposer substrate 10, wherein the bonding conductors 1062 and the bonding conductors 1142 are bonded to each other via metal-to-metal bonding, and the bonding dielectric layer 1060 and the bonding dielectric layer 1140 are bonded to each other via dielectric-to-dielectric fusion bonding. In some alternative embodiments, although not shown, the plurality of semiconductor dies 11 are bonded to the interposer substrate 10 using conductive connectors such as metal pillars, micro bumps or combinations thereof, and an underfill may be provided by capillary underfill filling (CUF) to fill the interstices between the interposer substrate 10 and the plurality of semiconductor dies 11 so as to protect the conductive connectors against thermal or physical stresses.

Referring to FIG. 1B, the manufacturing method may further include forming a first encapsulant layer 12 on the interposer substrate 10 and surrounding the plurality of semiconductor dies 11. In some embodiments, the first encapsulant layer 12 is formed by a molding process (e.g., an over-molding process or a compression molding process) followed by a planarization process.

For example, an encapsulation material (not shown) is formed over the interposer substrate 10 to at least encapsulate the plurality of semiconductor dies 11. In some embodiments, the plurality of semiconductor dies 11 are fully covered and not revealed by the encapsulation material. In some embodiments, the encapsulation material may be a molding compound, a molding underfill, a resin (such as an epoxy resin), or the like. The encapsulation material is then partially removed by the planarization process until the rear surfaces SR11 of the plurality of semiconductor dies 11 are exposed. In some embodiments, upper portions of the plurality of semiconductor dies 11 may be removed during the planarization process. Planarization of the encapsulation material may produce an encapsulant (first encapsulant layer 12) that surrounds the plurality of semiconductor dies 11, but rear surfaces SR11 of the plurality of semiconductor dies 11 are exposed from the encapsulant (first encapsulant layer 12). In some embodiments, the planarization of the encapsulation material includes performing a mechanical grinding process and/or a chemical mechanical polishing (CMP) process. After the grinding process or the polishing process, rear surfaces SR11 of the plurality of semiconductor dies 11 may be substantially coplanar or level with a top surface ST12 of the first encapsulant layer 12.

Referring to FIG. 1C, the manufacturing method may further include forming a first backside metal layer 13 on the plurality of semiconductor dies 11 for better adhesion and connection reliability. The first backside metal layer 13 may be in contact with and cover the plurality of semiconductor dies 11. In some embodiments, the first backside metal layer 13 is a single layer or a multi-layered structure. In some embodiments, the material of the first backside metal layer 13 includes copper, titanium, titanium-copper alloy, gold, nickel, nickel-vanadium alloy, aluminum, other suitable metallic materials or a combination of at least two of the above.

In some embodiments, forming the first backside metal layer 13 on the plurality of semiconductor dies 11 includes forming the first backside metal layer 13 on the first encapsulant layer 12 and the plurality of semiconductor dies 11 via a deposition process (e.g., a sputtering process, a physical vapor deposition (PVD) process, a plating process, or the like) and patterning the first backside metal layer 13 via a patterning process so that the first backside metal layer 13 covers the plurality of semiconductor dies 11 and exposes at least a portion of the first encapsulant layer 12. For example, the first backside metal layer 13 overlapped with the first encapsulant layer 12 may be removed by using lithography and etching process, whereby a photoresist is deposited and patterned and then used as a mask during an etching process in order to remove the first encapsulant layer 12 overlapped with the first encapsulant layer 12.

Referring to FIG. 1D, the manufacturing method may further include bonding one or more heat dissipation elements 14 on the first backside metal layer 13. Even though two heat dissipation elements 14 are presented in FIG. 1D for illustrative purposes, it is understood that more than two heat dissipation elements 14 can be provided on the first backside metal layer 13.

In some embodiments, the number of the one or more heat dissipation elements 14 is equal to the number of the plurality of semiconductor dies 11, and the plurality of heat dissipation elements 14 and the plurality of semiconductor dies 11 may be in a one-to-one disposition relationship, namely, each of the heat dissipation elements 14 is respectively overlapped with a corresponding semiconductor die 11 among the plurality of semiconductor dies 11.

The one or more heat dissipation elements 14 have high thermal conductivity to improve heat dissipation efficiency. For example, the one or more heat dissipation elements 14 are one or more silicon bulks, but not limited thereto.

In some embodiments, bonding the one or more heat dissipation elements 14 on the first backside metal layer 13 includes forming a second backside metal layer 15 on the one or more heat dissipation elements 14 and bonding the second backside metal layer 15 to the first backside metal layer 13 through a solder layer 16. In some embodiments, the first backside metal layer 13, the second backside metal layer 15 and the solder layer 16 may have the same area as a total area of the plurality of semiconductor dies 11, but not limited thereto.

The second backside metal layer 15 may be in contact with and cover bottom surface(s) of the one or more heat dissipation elements 14. In some embodiments, the second backside metal layer 15 is a single layer or a multi-layered structure. In some embodiments, the material of the second backside metal layer 15 includes copper, titanium, titanium-copper alloy, gold, nickel, nickel-vanadium alloy, aluminum, other suitable metallic materials or a combination of at least two of the above.

The solder layer 16 may be formed on the second backside metal layer 15 prior to bonding the second backside metal layer 15 to the first backside metal layer 13. The one or more heat dissipation elements 14 with the second backside metal layer 15 and the solder layer 16 is/are placed on the first backside metal layer 13 through a pick-and-place method, in which the solder layer 16 faces the first backside metal layer 13. Then, a reflow process, a thermo compression bonding (TCB) process or a transient liquid phase (TLP) bonding process is performed to fix the heat dissipation element 14 on the plurality of semiconductor dies 11. In some alternative embodiments, the solder layer 16 is formed on the first backside metal layer 13 prior to bonding the second backside metal layer 15 to the first backside metal layer 13. Alternatively, the solder layer 16 may be formed on the first backside metal layer 13 and the second backside metal layer 15 prior to bonding the second backside metal layer 15 to the first backside metal layer 13.

FIG. 4A is an enlarged schematic view of the region R in FIG. 1D. As shown in FIG. 4A, each of the first backside metal layer 13 and the second backside metal layer 15 may be a stacked layer of two or more metallic layers. For example, the first backside metal layer 13 may include a first metallic layer 130 and a second metallic layer 132 sequentially formed on the rear surface SR11 of the semiconductor die 11, and the second backside metal layer 15 may include a first metallic layer 150 and a second metallic layer 152 sequentially formed on the bottom surface SB14 of the heat dissipation element 14. In some embodiments, the material of each of the first metallic layer 130 and the first metallic layer 150 includes titanium, and the material of each of the second metallic layer 132 and the second metallic layer 152 includes copper, but not limited thereto. In some alternative embodiments, the material of each of the first metallic layer 130 and the first metallic layer 150 includes titanium, and the material of each of the second metallic layer 132 and the second metallic layer 152 includes nickel, but not limited thereto.

FIG. 4B is another enlarged schematic view of the region R in FIG. 1D. As shown in FIG. 4B, the first metallic layer 130 may further include a third metallic layer 134 in addition to the first metallic layer 130 and the second metallic layer 132. The third metallic layer 134 may be formed on the second metallic layer 132 and disposed between the second metallic layer 132 and the solder layer 16 to prevent the second metallic layer 132 from oxidation and/or to improve the adhesion to the solder layer 16. In some embodiments, the material of the third metallic layer 134 includes gold, but not limited thereto.

FIG. 4C is yet another enlarged schematic view of the region R in FIG. 1D. As shown in FIG. 4C, the first metallic layer 130 may further include a fourth metallic layer 136 in addition to the first metallic layer 130, the second metallic layer 132 and the third metallic layer 134. The fourth metallic layer 136 may be formed on the rear surface SR11 of the semiconductor die 11 and disposed between the semiconductor die 11 and the first metallic layer 130. In some embodiments, the materials of the fourth metallic layer 136, the first metallic layer 130, the second metallic layer 132, the third metallic layer 134, the second metallic layer 152 and the first metallic layer 150 are respectively aluminum, titanium, nickel-vanadium alloy (NiV), gold, nickel (or copper) and titanium, but not limited thereto. The formation of intermetallic compound (IMC) can be reduced by the disposition of the NiV layer, and thus reliability of the bonding between the heat dissipation element 14 and the corresponding semiconductor die 11 can be increased.

Referring to FIG. 1E, the manufacturing method may further include forming a second encapsulant layer 17 on the first encapsulant layer 12, wherein the second encapsulant layer 17 surrounds the one or more heat dissipation elements 14 and overlaps the first encapsulant layer 12. In some embodiments, the second encapsulant layer 17 is formed by a molding process (e.g., an over-molding process or a compression molding process) followed by a planarization process.

For example, an encapsulation material (not shown) is formed over the first encapsulant layer 12 to at least encapsulate the one or more heat dissipation elements 14. In some embodiments, the one or more heat dissipation elements 14 is fully covered and not revealed by the encapsulation material. In some embodiments, the encapsulation material may be a molding compound, a molding underfill, a resin (such as an epoxy resin), or the like. In some embodiments, the first encapsulant layer 12 and the second encapsulant layer 17 are made of the same material. In some alternative embodiments, the first encapsulant layer 12 and the second encapsulant layer 17 are made of different materials. The encapsulation material is then partially removed by the planarization process until the top surface(s) ST14 of the one or more heat dissipation elements 14 is/are exposed. In some embodiments, upper portions of the one or more heat dissipation elements 14 may be removed during the planarization process, namely, the thickness TH14 of each heat dissipation element 14 may be reduced during the planarization process. Planarization of the encapsulation material may produce an encapsulant (second encapsulant layer 17) that surrounds the one or more heat dissipation elements 14, but the top surface(s) ST14 of the one or more heat dissipation elements 14 is/are exposed from the encapsulant (second encapsulant layer 17). In some embodiments, the planarization of the encapsulation material includes performing a mechanical grinding process and/or a chemical mechanical polishing (CMP) process. After the grinding process or the polishing process, the top surface(s) ST14 of the one or more heat dissipation elements 14 may be substantially coplanar or level with a top surface ST17 of the second encapsulant layer 17.

The manufacturing method may further include performing a singulation process SP after the second encapsulant layer 17 is formed (referring to FIG. 1H). In some embodiments, as shown in FIG. 1F, the manufacturing method may further include a carrier bonding process. Specifically, a carrier CR may be temporarily fixed on the one or more heat dissipation elements 14 and the second encapsulant layer 17 through a release layer RL. The carrier CR may include any suitable material that could provide structural support during semiconductor processing. In some embodiments, the material of the carrier CR includes metal (e.g., steel), glass, ceramic, silicon (e.g., bulk silicon), combinations thereof, multi-layers thereof, or the like, but other materials of the carrier CR are within the contemplated scope of the disclosure. The release layer RL may be optionally formed on the carrier CR for bonding and de-bonding the carrier CR from the one or more heat dissipation elements 14 and the second encapsulant layer 17. In some embodiments, the release layer RL includes a layer of light-to-heat-conversion (LTHC) release coating and a layer of associated adhesive (such as an ultra-violet (UV) curable adhesive or a heat curable adhesive layer) or the like, but other materials of the release layer RL are within the contemplated scope of the disclosure. In some embodiments, the one or more heat dissipation elements 14 and the second encapsulant layer 17 are attached to the release layer RL through a die attach film (DAF; not shown). The die attach film may be attached to the one or more heat dissipation elements 14 and the second encapsulant layer 17 before attaching to the release layer RL. Alternatively, the die attach film is omitted.

In some embodiments, as shown in FIG. 1G, the manufacturing method may further include a thinning process TP before the singulation process SP to partially remove or thin the semiconductor substrate 100 of the interposer substrate 10 until the through substrate vias 102 located in the semiconductor substrate 100 are exposed. In some embodiments, the thinning process TP may include a back-grinding process, a polishing process or an etching process. In some embodiments, after the thinning process TP, the thickness of the interposer substrate 100 is reduced.

After the thinning process TP, a dielectric layer 107 and conductive terminals 108 are sequentially formed on the thinned semiconductor substrate 100. The dielectric layer 107 may include a plurality of contact openings, and the conductive terminals 108 are exposed by the contact openings of the dielectric layer 107. In some embodiments, the dielectric layer 107 is formed through performing a chemical vapor deposition (CVD) process such as low-pressure CVD (LPCVD), plasma enhanced CVD (PECVD), and high-density plasma CVD (HDPCVD), and the material of the dielectric layer 107 includes silicon oxide, silicon nitride, undoped silicate glass material or a suitable dielectric material. In some embodiments, the conductive terminals 108 are formed in the contact openings of the dielectric layer 107 through a ball placement process, and the conductive terminals 108 include lead-free solder balls, solder balls, ball grid array (BGA) balls, bumps, C4 bumps or micro bumps.

Referring to FIG. 1H, after the conductive terminals 108 are formed, the carrier CR may be detached from the one or more heat dissipation elements 14 and the second encapsulant layer 17 by removing the release layer RL. For example, an external energy such as UV laser, visible light or heat, is applied to the release layer RL to lose its adhesiveness, so that the carrier CR may be detached from the one or more heat dissipation elements 14 and the second encapsulant layer 17. The die attach film described above (not shown, if existed) is optionally removed during or after removing the carrier CR.

Afterwards, a singulation process SP may be selectively performed to cut the second encapsulant layer 17, the first encapsulant layer 12 and the interposer substrate 10. For example, the semiconductor structure shown in FIG. 1H is attached to a tape frame (not shown) which holds the semiconductor structure in place during the singulation process. Subsequently, a cutting or singulation process may be performed on the semiconductor structure. For example, a mechanical saw (e.g., a blade saw), laser saw, or other suitable tool is used to cut across the semiconductor structure along scribe lines (refer to the dash lines in FIG. 1H; e.g., a series of cross lines along directions X and Y), so that several semiconductor packages (FIG. 1I schematically illustrates a semiconductor package 1) are separated, or singulated, from each other.

The efficiency of the singulation process SP can be improved and/or the lifetime of the tools used in the singulation process SP cab be prolonged by placing elements or layers (such as metal layers) that are difficult to cut outside the scribe lines. For example, the one or more heat dissipation elements 14, the first backside metal layer 13, the second backside metal layer 15 and the solder layer 16 are disposed in regions not traversed by the scribe lines (e.g., the heat dissipation elements 14, the first backside metal layer 13, the second backside metal layer 15 and the solder layer 16 are located between two adjacent scribe lines) to facilitate the singulation process SP and/or to improve integrated yield.

Referring to FIG. 1I, the semiconductor package 1 includes the interposer substrate 10, the plurality of semiconductor dies 11, the one or more heat dissipation elements 14 (e.g., one or more silicon bulks) and an encapsulant EN. The plurality of semiconductor dies 11 are disposed on the interposer substrate 10. The one or more heat dissipation elements 14 is/are disposed on the plurality of semiconductor dies 11. The encapsulant EN is disposed on the interposer substrate 10 and surrounds the plurality of semiconductor dies 11 and the one or more heat dissipation elements 14.

In some embodiments, the encapsulant EN is a stacked layer of the first encapsulant layer 12 and the second encapsulant layer 17. In some embodiments, the first encapsulant layer 12 and the second encapsulant layer 17 are made of the same material, and a physical boundary may or may not exist between the first encapsulant layer 12 and the second encapsulant layer 17. In some alternative embodiments, the first encapsulant layer 12 and the second encapsulant layer 17 are made of different materials, and a physical boundary may exist between the first encapsulant layer 12 and the second encapsulant layer 17.

In some embodiments, an outer edge (including an outer edge E1 of the first encapsulant layer 12 and an outer edge E2 of the second encapsulant layer 17) of the encapsulant EN is aligned with an edge E10 of the interposer substrate 10 as a result of the singulation process SP shown in FIG. 1H.

In some embodiments, the semiconductor package 1 further includes the first backside metal layer 13, the second backside metal layer 15 and the solder layer 16. The first backside metal layer 13 is disposed on the plurality of semiconductor dies 11 and between the plurality of semiconductor dies 11 and the one or more heat dissipation elements 14. The second backside metal layer 15 is disposed between the one or more heat dissipation elements 14 and the first backside metal layer 13. The solder layer 16 is disposed between the first backside metal layer 13 and the second backside metal layer 15. In some embodiments, the number of the one or more heat dissipation elements 14 is equal to the number of the plurality of semiconductor dies 11, and from a top view of the semiconductor package 1, the first backside metal layer 13, the second backside metal layer 15 and the solder layer 16 may have the same area as a total area of the plurality of semiconductor dies 11.

Under a fixed-size semiconductor package, the bonding area between each heat dissipation element and corresponding semiconductor die(s) reduces as the number of the heat dissipation elements increases. With the reduction of the bonding area, the influence of flatness on the formation of soldering void defects can be reduced, thereby reducing the generation of defects and/or improving bond quality or integrated yield. In addition, since the singulation process can be performed on areas between any two adjacent heat dissipation elements, the increase in the number of heat dissipation elements helps to reduce the size of the singulated semiconductor package.

Referring to FIG. 2A through FIG. 2I, a manufacturing method of a semiconductor package 1′ in accordance with some embodiments of the present disclosure is provided.

The step shown in FIG. 2A is similar to the step shown in FIG. 1A, so the detailed descriptions are not repeated for brevity.

Referring to FIG. 2B, the manufacturing method may further include forming the first backside metal layer 13 on the plurality of semiconductor dies 11 and the interposer substrate 10. For example, the first backside metal layer 13 is formed on the plurality of semiconductor dies 11 and the interposer substrate 10 via a deposition process (e.g., a sputtering process, a physical vapor deposition (PVD) process, a plating process, or the like). The first backside metal layer 13 may be in contact with and cover the plurality of semiconductor dies 11 and the interposer substrate 10. The first backside metal layer 13 in FIG. 2B is similar to the first backside metal layer 13 in FIG. 1C, FIG. 4A, FIG. 4B or FIG. 4C, so the detailed descriptions are not repeated for brevity.

Optionally, a planarization process (not shown) is performed on the semiconductor substrates 110 of the plurality of semiconductor dies 11 prior to the formation of the first backside metal layer 13 to facilitate subsequent bonding with the plurality of heat dissipation elements 14 shown in FIG. 2C, reducing the time for subsequent formation of the encapsulant EN shown in FIG. 2D or reducing warpage.

Referring to FIG. 2C, the manufacturing method may further include forming the second backside metal layer 15 on the plurality of heat dissipation elements 14 and bonding the second backside metal layer 15 to the first backside metal layer 13 located on the plurality of semiconductor dies 11 through the solder layer 16 so as to bond the plurality of heat dissipation elements 14 respectively on the plurality of semiconductor dies 11, wherein the plurality of heat dissipation elements 14 are respectively overlapped with the plurality of semiconductor dies 11 and expose the first backside metal layer 13 that surrounds the plurality of semiconductor dies 11. The second backside metal layer 15 and the solder layer 16 in FIG. 2C are similar to the second backside metal layer 15 and the solder layer 16 shown in FIG. 1D, FIG. 4A, FIG. 4B or FIG. 4C, so the detailed descriptions are not repeated for brevity.

Referring to FIG. 2D, the manufacturing method may further include patterning the first backside metal layer 13 via a patterning process so that the first backside metal layer 13 covers the plurality of semiconductor dies 11 and exposes the interposer substrate 10 not covered by the plurality of semiconductor dies 11. For example, the first backside metal layer 13 that surrounds the plurality of semiconductor dies 11 may be removed by using lithography and etching process, whereby a photoresist is deposited and patterned and then used as a mask during an etching process in order to remove the first backside metal layer 13 not overlapped with the plurality of semiconductor dies 11.

Referring to FIG. 2E, the manufacturing method may further include forming an encapsulant EN′ on the interposer substrate 10, wherein the encapsulant EN′ surrounds the plurality of semiconductor dies 11 and the plurality of heat dissipation elements 14. In some embodiments, the encapsulant EN′ is formed by a molding process (e.g., an over-molding process or a compression molding process) followed by a planarization process.

For example, an encapsulation material (not shown) is formed over the interposer substrate 10 to at least encapsulate the plurality of semiconductor dies 11 and the plurality of heat dissipation elements 14. In some embodiments, the plurality of semiconductor dies 11 and the plurality of heat dissipation elements 14 are fully covered and not revealed by the encapsulation material. In some embodiments, the encapsulation material may be a molding compound, a molding underfill, a resin (such as an epoxy resin), or the like. The encapsulation material is then partially removed by the planarization process until top surfaces ST14 of the plurality of heat dissipation elements 14 are exposed. In some embodiments, upper portions of the plurality of heat dissipation elements 14 may be removed during the planarization process. Planarization of the encapsulation material may produce an encapsulant (the encapsulant EN′) that surrounds the plurality of semiconductor dies 11 and the plurality of heat dissipation elements 14, but the top surfaces ST14 of the plurality of heat dissipation elements 14 are exposed from the encapsulant EN′. In some embodiments, the planarization of the encapsulation material includes performing a mechanical grinding process and/or a chemical mechanical polishing (CMP) process. After the grinding process or the polishing process, the top surfaces ST14 of the plurality of heat dissipation elements 14 may be substantially coplanar or level with a top surface STEN′ of the encapsulant EN′. In some embodiments, the encapsulant EN′ is a single layer formed by a single molding process.

The steps shown in FIG. 2F and FIG. 2G are similar to the steps shown in FIG. 1F and FIG. 1G, so the detailed descriptions are not repeated for brevity.

Referring to FIG. 2H, after the conductive terminals 108 are formed (as shown in FIG. 2G), the carrier CR may be detached from the one or more heat dissipation elements 14 and the encapsulant EN′ by removing the release layer RL. For example, an external energy such as UV laser, visible light or heat, is applied to the release layer RL to lose its adhesiveness, so that the carrier CR may be detached from the one or more heat dissipation elements 14 and the encapsulant EN′. The die attach film on the one or more heat dissipation elements 14 and the encapsulant EN′ (not shown, if existed) is optionally removed during or after removing the carrier CR.

Afterwards, a singulation process SP may be selectively performed to cut the encapsulant EN′ and the interposer substrate 10. For example, the semiconductor structure shown in FIG. 2H is attached to a tape frame (not shown) which holds the semiconductor structure in place during the singulation process. Subsequently, a cutting or singulation process may be performed on the semiconductor structure. For example, a mechanical saw (e.g., a blade saw), laser saw, or other suitable tool is used to cut across the semiconductor structure along scribe lines (refer to the dash lines in FIG. 2H; e.g., a series of cross lines along directions X and Y), so that several semiconductor packages (FIG. 2I schematically illustrates a semiconductor package 1′) are separated, or singulated, from each other.

The efficiency of the singulation process SP can be improved and/or the lifetime of the tools used in the singulation process SP cab be prolonged by placing elements or layers (such as metal layers) that are difficult to cut outside the scribe lines. For example, the one or more heat dissipation elements 14, the first backside metal layer 13, the second backside metal layer 15 and the solder layer 16 are disposed in regions not traversed by the scribe lines to facilitate the singulation process SP and/or to improve integrated yield.

Referring to FIG. 2I, the semiconductor package 1′ includes the interposer substrate 10, the plurality of semiconductor dies 11, the one or more heat dissipation elements 14 (e.g., one or more silicon bulks) and the encapsulant EN′. The plurality of semiconductor dies 11 are disposed on the interposer substrate 10. The one or more heat dissipation elements 14 is/are disposed on the plurality of semiconductor dies 11. The encapsulant EN′ is disposed on the interposer substrate 10 and surrounds the plurality of semiconductor dies 11 and the one or more heat dissipation elements 14.

In some embodiments, an outer edge E′ of the encapsulant EN′ is aligned with an edge E10 of the interposer substrate 10 as a result of the singulation process SP shown in FIG. 2H.

In some embodiments, the semiconductor package 1′ further includes the first backside metal layer 13, the second backside metal layer 15 and the solder layer 16. The first backside metal layer 13 is disposed on the plurality of semiconductor dies 11 and between the plurality of semiconductor dies 11 and the one or more heat dissipation elements 14. The second backside metal layer 15 is disposed between the one or more heat dissipation elements 14 and the first backside metal layer 13. The solder layer 16 is disposed between the first backside metal layer 13 and the second backside metal layer 15. In some embodiments, the number of the one or more heat dissipation elements 14 is equal to the number of the plurality of semiconductor dies 11, and from a top view of the semiconductor package 1′, the first backside metal layer 13, the second backside metal layer 15 and the solder layer 16 may have the same area as a total area of the plurality of semiconductor dies 11.

Referring to FIG. 3A through FIG. 3I, a manufacturing method of a semiconductor package 1″ in accordance with some embodiments of the present disclosure is provided.

The steps shown in FIG. 3A and FIG. 3B are similar to the steps shown in FIG. 1A and FIG. 1B, so the detailed descriptions are not repeated for brevity.

Referring to FIG. 3C, the manufacturing method may further include forming a first backside metal layer 13 on the plurality of semiconductor dies 11 for better adhesion and connection reliability. In some embodiments, forming the first backside metal layer 13 on the plurality of semiconductor dies 11 includes forming the first backside metal layer 13 on the first encapsulant layer 12 and the plurality of semiconductor dies 11 via a deposition process (e.g., a sputtering process, a physical vapor deposition (PVD) process, a plating process, or the like).

Referring to FIG. 3D, the manufacturing method may further include bonding one or more heat dissipation elements 14 on the first backside metal layer 13. Even though one heat dissipation element 14 is presented in FIG. 3D for illustrative purposes, it is understood that more than one heat dissipation elements 14 can be provided on the first backside metal layer 13.

In some embodiments, the number of the one or more heat dissipation elements 14 is less than the number of the plurality of semiconductor dies 11, and the plurality of heat dissipation elements 14 and the plurality of semiconductor dies 11 may be in a many-to-one disposition relationship, namely, each of the heat dissipation elements 14 is respectively overlapped with more than one semiconductor dies 11 among the plurality of semiconductor dies 11.

In some embodiments, bonding the one or more heat dissipation elements 14 on the first backside metal layer 13 includes forming a second backside metal layer 15 on the one or more heat dissipation elements 14 and bonding the second backside metal layer 15 to the first backside metal layer 13 through a solder layer 16. In some embodiments, the first backside metal layer 13, the second backside metal layer 15 and the solder layer 16 may have the same area as a total area of the one or more heat dissipation elements 14, but not limited thereto.

Referring to FIG. 3E, the manufacturing method may further include patterning the first backside metal layer 13 via a patterning process so that the first backside metal layer 13 covers the plurality of semiconductor dies 11 and exposes the first encapsulant layer 12 that is not overlapped with the one or more heat dissipation elements 14. For example, the first backside metal layer 13 that is not overlapped with the one or more heat dissipation elements 14 may be removed by using lithography and etching process, whereby a photoresist is deposited and patterned and then used as a mask during an etching process in order to remove the first backside metal layer 13 that is not overlapped with the one or more heat dissipation elements 14. In other words, the first backside metal layer 13 is patterned after the one or more heat dissipation elements 14 are bonded on the first backside metal layer 13.

The manufacturing method may further include forming a second encapsulant layer 17 on the first encapsulant layer 12 that is exposed by the first backside metal layer 13, wherein the second encapsulant layer 17 surrounds the one or more heat dissipation elements 14 and overlaps the first encapsulant layer 12. In some embodiments, the second encapsulant layer 17 is formed by a molding process (e.g., an over-molding process or a compression molding process) followed by a planarization process.

For example, an encapsulation material (not shown) is formed over the first encapsulant layer 12 to at least encapsulate the one or more heat dissipation elements 14. In some embodiments, the one or more heat dissipation elements 14 is fully covered and not revealed by the encapsulation material. In some embodiments, the encapsulation material may be a molding compound, a molding underfill, a resin (such as an epoxy resin), or the like. In some embodiments, the first encapsulant layer 12 and the second encapsulant layer 17 are made of the same material. In some alternative embodiments, the first encapsulant layer 12 and the second encapsulant layer 17 are made of different materials. The encapsulation material is then partially removed by the planarization process until the top surface(s) ST14 of the one or more heat dissipation elements 14 is/are exposed. In some embodiments, upper portions of the one or more heat dissipation elements 14 may be removed during the planarization process, namely, the thickness TH14 of each heat dissipation element 14 may be reduced during the planarization process. Planarization of the encapsulation material may produce an encapsulant (second encapsulant layer 17) that surrounds the one or more heat dissipation elements 14, but the top surface(s) ST14 of the one or more heat dissipation elements 14 is/are exposed from the encapsulant (second encapsulant layer 17). In some embodiments, the planarization of the encapsulation material includes performing a mechanical grinding process and/or a chemical mechanical polishing (CMP) process. After the grinding process or the polishing process, the top surface(s) ST14 of the one or more heat dissipation elements 14 may be substantially coplanar or level with a top surface ST17 of the second encapsulant layer 17.

The steps shown in FIG. 3F and FIG. 3H are similar to the steps shown in FIG. 1F and FIG. 1H, so the detailed descriptions are not repeated for brevity.

Referring to FIG. 3I, the semiconductor package 1″ includes the interposer substrate 10, the plurality of semiconductor dies 11, one heat dissipation element 14 (e.g., one silicon bulk) and the encapsulant EN. The plurality of semiconductor dies 11 are disposed on the interposer substrate 10. The heat dissipation element 14 is disposed on the plurality of semiconductor dies 11. The encapsulant EN is disposed on the interposer substrate 10 and surrounds the plurality of semiconductor dies 11 and the heat dissipation element 14.

In some embodiments, the encapsulant EN is a stacked layer of the first encapsulant layer 12 and the second encapsulant layer 17. In some embodiments, the first encapsulant layer 12 and the second encapsulant layer 17 are made of the same material, and a physical boundary may or may not exist between the first encapsulant layer 12 and the second encapsulant layer 17. In some alternative embodiments, the first encapsulant layer 12 and the second encapsulant layer 17 are made of different materials, and a physical boundary may exist between the first encapsulant layer 12 and the second encapsulant layer 17.

In some embodiments, an outer edge (including the outer edge E1 of the first encapsulant layer 12 and the outer edge E2 of the second encapsulant layer 17) of the encapsulant EN is aligned with an edge E10 of the interposer substrate 10 as a result of the singulation process SP shown in FIG. 3H.

In some embodiments, the semiconductor package 1″ further includes the first backside metal layer 13, the second backside metal layer 15 and the solder layer 16. The first backside metal layer 13 is disposed on the plurality of semiconductor dies 11 and between the plurality of semiconductor dies 11 and the heat dissipation element 14. The second backside metal layer 15 is disposed between the heat dissipation element 14 and the first backside metal layer 13. The solder layer 16 is disposed between the first backside metal layer 13 and the second backside metal layer 15. In some embodiments, the number of the one or more heat dissipation elements 14 is one, and from a top view of the semiconductor package 1″, the first backside metal layer 13, the second backside metal layer 15 and the solder layer 16 may have the same area as the heat dissipation element 14.

Based on the above discussions, it can be seen that the present disclosure offers various advantages. It is understood, however, that not all advantages are necessarily discussed herein, and other embodiments may offer different advantages, and that no particular advantage is required for all embodiments.

In accordance with some embodiments of the present disclosure, a semiconductor package includes an interposer substrate, a plurality of semiconductor dies, one or more heat dissipation elements and an encapsulant. The plurality of semiconductor dies are disposed on the interposer substrate. The one or more heat dissipation elements are disposed on the plurality of semiconductor dies. The encapsulant is disposed on the interposer substrate and surrounds the plurality of semiconductor dies and the one or more heat dissipation elements. In some embodiments, the number of the one or more heat dissipation elements is equal to the number of the plurality of semiconductor dies, and each of the heat dissipation elements is respectively overlapped with a corresponding semiconductor die among the plurality of semiconductor dies. In some embodiments, the encapsulant is a single layer. In some embodiments, the encapsulant is a stacked layer of a first encapsulant layer and a second encapsulant layer, rear surfaces of the plurality of semiconductor dies are level with a top surface of the first encapsulant layer, and top surfaces of the heat dissipation elements are level with a top surface of the second encapsulant layer. In some embodiments, the number of the one or more heat dissipation elements is one, and the heat dissipation element is overlapped with the plurality of semiconductor dies. In some embodiments, the encapsulant is a stacked layer of a first encapsulant layer and a second encapsulant layer, rear surfaces of the plurality of semiconductor dies are level with a top surface of the first encapsulant layer, and a top surface of the heat dissipation element is level with a top surface of the second encapsulant layer. In some embodiments, the one or more heat dissipation elements are one or more silicon bulks. In some embodiments, the semiconductor package further includes a first backside metal layer disposed on the plurality of semiconductor dies, a second backside metal layer disposed between the one or more heat dissipation elements and the first backside metal layer and a solder layer disposed between the first backside metal layer and the second backside metal layer. In some embodiments, the number of the one or more heat dissipation elements is one, and the first backside metal layer, the second backside metal layer and the solder layer have the same area as that of the heat dissipation element. In some embodiments, the number of the one or more heat dissipation elements is equal to the number of the plurality of semiconductor dies, and the first backside metal layer, the second backside metal layer and the solder layer have the same area as a total area of the plurality of semiconductor dies. In some embodiments, each of the first backside metal layer and the second backside metal layer is a stacked layer of two or more metallic layers. In some embodiments, an outer edge of the encapsulant is aligned with an edge of the interposer substrate.

In accordance with some embodiments of the present disclosure, a manufacturing method of a semiconductor package includes: bonding a plurality of semiconductor dies on an interposer substrate; forming a first encapsulant layer on the interposer substrate and surrounding the plurality of semiconductor dies; forming a first backside metal layer on the plurality of semiconductor dies; bonding one or more heat dissipation elements on the first backside metal layer; forming a second encapsulant layer on the first encapsulant layer, wherein the second encapsulant layer surrounds the one or more heat dissipation elements and overlaps the first encapsulant layer; and performing a singulation process to cut the second encapsulant layer, the first encapsulant layer and the interposer substrate. In some embodiments, bonding the one or more heat dissipation elements on the first backside metal layer includes: forming a second backside metal layer on the one or more heat dissipation elements; and bonding the second backside metal layer to the first backside metal layer through a solder layer. In some embodiments, forming the first backside metal layer on the plurality of semiconductor dies includes: forming the first backside metal layer on the first encapsulant layer and the plurality of semiconductor dies; and patterning the first backside metal layer so that the first backside metal layer covers the plurality of semiconductor dies and exposes at least a portion of the first encapsulant layer. In some embodiments, the first backside metal layer is patterned before the one or more heat dissipation elements are bonded on the first backside metal layer. In some embodiments, the first backside metal layer is patterned after the one or more heat dissipation elements are bonded on the first backside metal layer. In some embodiments, the first encapsulant layer and the second encapsulant layer are made of the same material.

In accordance with alternative embodiments of the present disclosure, a manufacturing method of a semiconductor package includes: bonding a plurality of semiconductor dies on an interposer substrate; bonding a plurality of heat dissipation elements respectively on the plurality of semiconductor dies; forming an encapsulant that surrounds the plurality of semiconductor dies and the plurality of heat dissipation elements on the interposer substrate; and performing a singulation process to cut the encapsulant and the interposer substrate. In some embodiments, bonding the plurality of heat dissipation elements respectively on the plurality of semiconductor dies includes: forming a first backside metal layer on the plurality of semiconductor dies; forming a second backside metal layer on the plurality of heat dissipation elements; and bonding the second backside metal layer to the first backside metal layer through a solder layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
an interposer substrate;
a plurality of semiconductor dies disposed on the interposer substrate;
one or more heat dissipation elements disposed on the plurality of semiconductor dies; and
an encapsulant disposed on the interposer substrate and surrounding the plurality of semiconductor dies and the one or more heat dissipation elements.

2. The semiconductor package according to claim 1, wherein the number of the one or more heat dissipation elements is equal to the number of the plurality of semiconductor dies, and
each of the heat dissipation elements is respectively overlapped with a corresponding semiconductor die among the plurality of semiconductor dies.

3. The semiconductor package according to claim 2, wherein the encapsulant is a single layer.

4. The semiconductor package according to claim 2, wherein the encapsulant is a stacked layer of a first encapsulant layer and a second encapsulant layer,
rear surfaces of the plurality of semiconductor dies are level with a top surface of the first encapsulant layer, and
top surfaces of the heat dissipation elements are level with a top surface of the second encapsulant layer.

5. The semiconductor package according to claim 1, wherein the number of the one or more heat dissipation elements is one, and
the heat dissipation element is overlapped with the plurality of semiconductor dies.

6. The semiconductor package according to claim 5, wherein the encapsulant is a stacked layer of a first encapsulant layer and a second encapsulant layer,
rear surfaces of the plurality of semiconductor dies are level with a top surface of the first encapsulant layer, and
a top surface of the heat dissipation element is level with a top surface of the second encapsulant layer.

7. The semiconductor package according to claim 1, wherein the one or more heat dissipation elements are one or more silicon bulks.

8. The semiconductor package according to claim 7, further comprising:
a first backside metal layer disposed on the plurality of semiconductor dies;
a second backside metal layer disposed between the one or more heat dissipation elements and the first backside metal layer; and
a solder layer disposed between the first backside metal layer and the second backside metal layer.

9. The semiconductor package according to claim 8, wherein the number of the one or more heat dissipation elements is one, and
the first backside metal layer, the second backside metal layer and the solder layer have the same area as that of the heat dissipation element.

10. The semiconductor package according to claim 8, wherein the number of the one or more heat dissipation elements is equal to the number of the plurality of semiconductor dies, and
the first backside metal layer, the second backside metal layer and the solder layer have the same area as a total area of the plurality of semiconductor dies.

11. The semiconductor package according to claim 8, wherein each of the first backside metal layer and the second backside metal layer is a stacked layer of two or more metallic layers.

12. The semiconductor package according to claim 1, wherein an outer edge of the encapsulant is aligned with an edge of the interposer substrate.

13. A manufacturing method of a semiconductor package, comprising:
bonding a plurality of semiconductor dies on an interposer substrate;
forming a first encapsulant layer on the interposer substrate and surrounding the plurality of semiconductor dies;
forming a first backside metal layer on the plurality of semiconductor dies;
bonding one or more heat dissipation elements on the first backside metal layer;
forming a second encapsulant layer on the first encapsulant layer, wherein the second encapsulant layer surrounds the one or more heat dissipation elements and overlaps the first encapsulant layer; and
performing a singulation process to cut the second encapsulant layer, the first encapsulant layer and the interposer substrate.

14. The manufacturing method of the semiconductor package according to claim 13, wherein bonding the one or more heat dissipation elements on the first backside metal layer comprises:
forming a second backside metal layer on the one or more heat dissipation elements; and
bonding the second backside metal layer to the first backside metal layer through a solder layer.

15. The manufacturing method of the semiconductor package according to claim 14, wherein forming the first backside metal layer on the plurality of semiconductor dies comprises:
forming the first backside metal layer on the first encapsulant layer and the plurality of semiconductor dies; and
patterning the first backside metal layer so that the first backside metal layer covers the plurality of semiconductor dies and exposes at least a portion of the first encapsulant layer.

16. The manufacturing method of the semiconductor package according to claim 15, wherein the first backside metal layer is patterned before the one or more heat dissipation elements are bonded on the first backside metal layer.

17. The manufacturing method of the semiconductor package according to claim 15, wherein the first backside metal layer is patterned after the one or more heat dissipation elements are bonded on the first backside metal layer.

18. The manufacturing method of the semiconductor package according to claim 13, wherein the first encapsulant layer and the second encapsulant layer are made of the same material.

19. A manufacturing method of a semiconductor package, comprising:
bonding a plurality of semiconductor dies on an interposer substrate;
bonding a plurality of heat dissipation elements respectively on the plurality of semiconductor dies;
forming an encapsulant that surrounds the plurality of semiconductor dies and the plurality of heat dissipation elements on the interposer substrate; and
performing a singulation process to cut the encapsulant and the interposer substrate.

20. The manufacturing method of the semiconductor package according to claim 19, wherein bonding the plurality of heat dissipation elements respectively on the plurality of semiconductor dies comprises:
forming a first backside metal layer on the plurality of semiconductor dies;
forming a second backside metal layer on the plurality of heat dissipation elements; and
bonding the second backside metal layer to the first backside metal layer through a solder layer.
